(19) United States
(12) Patent Application Publication
(10) Pub. No.: US 2024/0038492 A1
(43) Pub. Date: Feb. 1, 2024

(54) SUBSTRATE SUPPORTING APPARATUS, SUBSTRATE PROCESSING SYSTEM INCLUDING THE SAME, AND MANUFACTURING METHOD THEREOF

(71) Applicant: SAMSUNG ELECTRONICS CO., LTD., Suwon-si (KR)

(72) Inventors: HYUNGJOON KIM, Suwon-si (KR); KIYONG KIM, Suwon-si (KR); YOUNGKWON KIM, Suwon-si (KR); JAEHYUN KIM, Suwon-si (KR); YOODONG YANG, Suwon-si (KR); MINSUCK YOO, Suwon-si (KR); JONGHYUN LEE, Suwon-si (KR); ILJUN JEON, Suwon-si (KR); HEE JONG JEONG, Suwon-si (KR)

(73) Assignee: SAMSUNG ELECTRONICS CO., LTD., Suwon-si (KR)

(21) Appl. No.: 18/121,103

(22) Filed: Mar. 14, 2023

(30) Foreign Application Priority Data
Aug. 1, 2022 (KR) 10-2022-0095573

(51) Int. Cl. H01J 37/32

(52) U.S. Cl. CPC H01J 37/32082; H01J 37/32532; H01J 37/32724; H01J 2237/3321

(57) ABSTRACT

A substrate supporting apparatus includes a heating plate, a radio frequency (RF) electrode in the heating plate, and an RF delivery structure in contact with a bottom surface of the RF electrode. The heating plate includes a first insertion hole, which is recessed into the heating plate from a bottom surface of the heating plate to expose the bottom surface of the RF electrode. The RF delivery structure includes an RF rod, a portion of which is inserted in the first insertion hole, and through which an RF power is supplied to the RF electrode. The RF rod includes a first material, and a relative permeability of the first material is less than 100, a volume resistivity of the first material is smaller than 70 nΩm, and a melting point of the first material is higher than 1400° C.

### CROSS-REFERENCE TO RELATED APPLICATIONS

This U.S. non-provisional patent application claims priority under 35 U.S.C. § 119 to Korean Patent Application No. 10-2022-0095573, filed on Aug. 1, 2022, in the Korean Intellectual Property Office, the entire contents of which being hereby incorporated by reference.

### BACKGROUND

The present disclosure relates to a substrate supporting apparatus, a substrate processing system including the same, and a method of manufacturing the same, and in particular, to a substrate supporting apparatus, which is configured to reduce a resistance of a rod for power delivery, a substrate processing system including the same, and a method of manufacturing the same.

A semiconductor device may be fabricated through various processes. For example, the semiconductor device may be fabricated by performing a photolithography process, an etching process, and a deposition process on a silicon wafer. Plasma may be used in the deposition process. For example, in a plasma-enhanced chemical vapor deposition (PE-CVD) process, a deposition process on a substrate is performed using plasma. In the PE-CVD process, the substrate is fastened by a substrate supporting apparatus which may be heated to control a temperature of the substrate.

### SUMMARY

It is an aspect to provide a substrate supporting apparatus capable of economizing on electric power, a substrate processing system including the same, and a method of manufacturing the same.

It is another aspect to provide a substrate supporting apparatus capable of suppressing a heat generating effect, a substrate processing system including the same, and a method of manufacturing the same.

It is yet another aspect to provide a substrate supporting apparatus with an increased lifetime, a substrate processing system including the same, and a method of manufacturing the same.

It is a further aspect to provide a substrate supporting apparatus, which can be easily assembled, a substrate processing system including the same, and a method of manufacturing the same.

According to an aspect of one or more embodiments, there is provided a substrate supporting apparatus comprising a heating plate; a radio frequency (RF) electrode in the heating plate; and an RF delivery structure in contact with a bottom surface of the RF electrode, wherein the heating plate includes a first insertion hole, which is recessed into the heating plate from a bottom surface of the heating plate to expose the bottom surface of the RF electrode, the RF delivery structure includes an RF rod, a portion of which is inserted in the first insertion hole, and through which an RF power is supplied to the RF electrode, the RF rod comprises a first material, a relative permeability of the first material is less than 100, a volume resistivity of the first material is smaller than 70 nΩm, and a melting point of the first material is higher than 1400° C.

According to another aspect of one or more embodiments, there is provided a substrate processing system comprising a chamber providing a process space; and a substrate supporting apparatus placed in the chamber to support a substrate. The substrate supporting apparatus comprises a heating plate; a radio frequency (RF) electrode in the heating plate; a heater in the heating plate; an RF delivery structure in contact with a bottom surface of the RF electrode; and a heater power delivery structure, which is in contact with the heater and is spaced apart from the RF delivery structure in a horizontal direction. The heating plate comprises a first insertion hole, which is recessed into the heating plate from a bottom surface of the heating plate to expose the bottom surface of the RF electrode; and a second insertion hole, which is recessed into the heating plate from the bottom surface of the heating plate to expose the heater and is spaced apart from the first insertion hole in the horizontal direction. The RF delivery structure comprises an RF rod, which is vertically extended and includes a portion that is inserted in the first insertion hole. The heater power delivery structure comprises a heater power rod, which is vertically extended and includes a portion that is inserted in the second insertion hole, and each of the RF rod and the heater power rod comprises molybdenum.

According to another aspect of one or more embodiments, there is provided a method of manufacturing a substrate processing system, the method comprising inserting a portion of a radio frequency (RF) delivery structure in a first insertion hole of a heating plate; and bonding the RF delivery structure to an RF electrode in the heating plate, wherein the RF delivery structure comprises a first coupling member, a first filler, and an RF rod, and inserting the portion of the RF delivery structure in the first insertion hole comprises inserting the first coupling member in the first insertion hole to be in contact with a bottom surface of the RF electrode; inserting the first filler in the first insertion hole to be in contact with a bottom surface of the first coupling member; and inserting the RF rod in the first insertion hole to be in contact with a bottom surface of the first filler, bonding the RF delivery structure to the RF electrode comprises heating the heating plate when the RF rod is in contact with the bottom surface of the first filler, and each of the first coupling member and the RF rod comprises molybdenum.

### BRIEF DESCRIPTION OF THE DRAWINGS

The above and other aspects will be described with reference to the accompanying drawings, in which:

FIG. 1 is a sectional view illustrating a substrate processing system according to some embodiments;

FIG. 2 is an enlarged sectional view illustrating a portion ‘X’ of FIG. 1, according to some embodiments;

FIG. 3 is an exploded sectional view of FIG. 2, according to some embodiments;

FIG. 4 is a flow chart illustrating a method of manufacturing a substrate processing system, according to some embodiments;

FIGS. 5 to 8 are sectional views sequentially illustrating a method of manufacturing a substrate processing system according to the flow chart of FIG. 4, according to some embodiments;

FIG. 9 is a flow chart illustrating a substrate processing method according to some embodiments;

FIGS. 10 to 12 are sectional views illustrating a substrate processing method according to the flow chart of FIG. 9, according to some embodiments; and

FIG. 13 is an exploded sectional view illustrating a radio frequency (RF) delivery structure according to some embodiments.

### DETAILED DESCRIPTION

Various example embodiments will now be described more fully with reference to the accompanying drawings, in which example embodiments are shown. Like reference numerals in the drawings denote like elements, and thus repeated description will be omitted for conciseness.

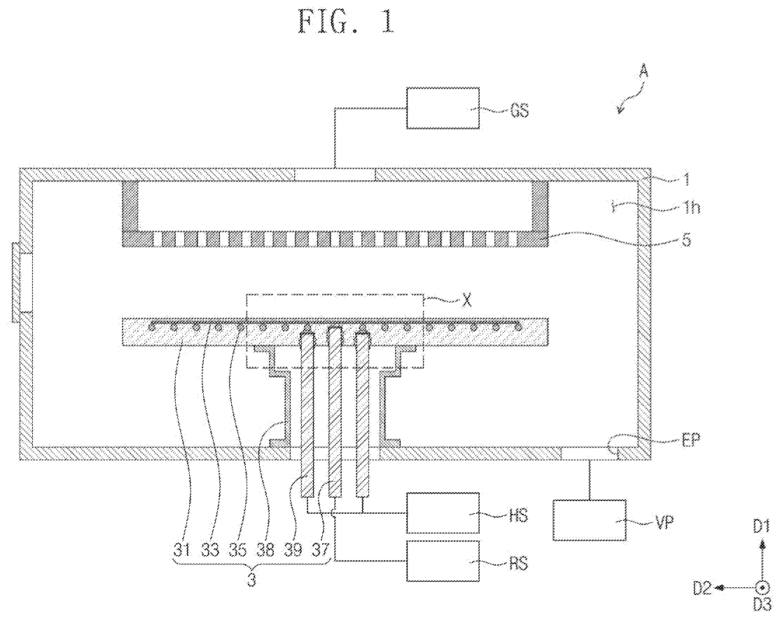

FIG. 1 is a sectional view illustrating a substrate processing system according to some embodiments.

In the present application, as shown in FIG. 1, the reference numbers D1, D2, and D3 will be used to denote a first direction, a second direction, and a third direction, respectively, which are not parallel to each other. The first direction D1 may be referred to as a vertical direction. Each of the second and third directions D2 and D3 may be referred to as a horizontal direction.

Referring to FIG. 1, a substrate processing system A may be provided. The substrate processing system A may be configured to perform a process on a substrate using plasma. For example, the substrate processing system A may be configured to perform a deposition process on the substrate. More specifically, the substrate processing system A may be a system that is configured to perform a plasma-enhanced chemical vapor deposition (PE-CVD) process on the substrate. In the present specification, the substrate may be a silicon wafer, but the embodiments are not limited to this example. The substrate processing system A may include a chamber 1, a substrate supporting apparatus 3, a shower head 5, a gas supplying device GS, a radio frequency (RF) power supplying device RS, a heater power supplying device HS, and a pump VP.

The chamber 1 may provide a process space 1h. The chamber 1 may be provided to separate the process space 1h from an external space. In the process space 1h, a deposition process on the substrate may be performed. The chamber 1 may be provided to have an exhaust port EP. The process space 1h may be connected to the pump VP through the exhaust port EP.

The substrate supporting apparatus 3 may be placed in the chamber 1. The substrate supporting apparatus 3 may be configured to support and/or fasten the substrate. In some embodiments, the substrate supporting apparatus 3 may be configured to control a temperature of the substrate. For example, the substrate supporting apparatus 3 may be configured to heat the substrate. To heat the substrate, the substrate supporting apparatus 3 may include a heating plate 31, an RF electrode 33, a heater 35, an RF delivery structure 37, a heater power delivery structure 39, and a protection shaft 38.

The heating plate 31 may be provided to support the substrate. In other words, the substrate may be placed on a top surface of the heating plate 31. The heating plate 31 may be a shape of a circular plate that is extended in a horizontal direction, but the embodiments are not limited to this example. In an embodiment, the heating plate 31 may be formed of or include aluminum nitride (AlN). This configuration will be described in more detail below.

The RF electrode 33 may be placed in the heating plate 31. For example, the RF electrode 33 may be buried in the heating plate 31. The RF electrode 33 may be formed of or include at least one of conductive materials. For example, the RF electrode 33 may be formed of or include molybdenum (Mo). The RF electrode 33 may be electrically connected to the RF delivery structure 37. The RF electrode 33 may be a mesh-shaped plate, but the embodiments are not limited to this example. The RF electrode 33 will be described in more detail below.

The heater 35 may be placed in the heating plate 31. For example, the heater 35 may be buried in the heating plate 31. The heater 35 may be located below the RF electrode 33. The heater 35 may be formed of or include at least one of conductive materials. For example, in some embodiments, the heater 35 may be formed of or include the same material as the RF electrode 33. More specifically, in some embodiments, the heater 35 may be formed of or include molybdenum (Mo). The heater 35 may be electrically connected to the heater power delivery structure 39. The heater 35 may be configured to generate heat from an electric energy. Due to the heating process of the heater 35, the heating plate 31 may have an increased temperature. In some embodiments, the substrate on the heating plate 31 may be heated by the heater 35. In an embodiment, the heater 35 may include a heating line. The heater 35, which is provided in the form of the heating line, may be provided to enclose a portion of the RF delivery structure 37, when viewed in a plan view. In an embodiment, the heater 35 may include two or more heating lines, which are not connected to each other. For example, in some embodiments, the heater 35 may include a plurality of heating lines that are rod-shaped and extend in the direction D3 along a plane of the heating plate 31 as illustrated in FIGS. 1-3. The heater 35 will be described in more detail below.

The RF delivery structure 37 may be connected to the RF electrode 33. For example, the RF delivery structure 37 may be in contact with a bottom surface of an RF electrode. The RF delivery structure 37 may be configured to electrically connect the RF power supplying device RS to the RF electrode 33. The RF delivery structure 37 may apply an RF power to the RF electrode 33. In other words, the RF power may be supplied to the RF electrode 33 through the RF delivery structure 37. Due to the RF power applied to the RF electrode 33 through the RF delivery structure 37, an electromagnetic field may be produced in the process space 1h. Furthermore, the substrate on the heating plate 31 may be fastened to a specific position by the RF delivery structure 37. In an embodiment, a plurality of RF delivery structures 37 may be provided. For example, two RF delivery structures 37 may be provided. The RF two delivery structures 37 may be spaced apart from each other in a horizontal direction. However, for convenience in description, the description that follows will refer to an example, in which one RF delivery structure 37 is provided. The RF delivery structure 37 will be described in more detail below.

The heater power delivery structure 39 may be connected to the heater 35. For example, the heater power delivery structure 39 may be in contact with a bottom of the heater 35. The heater power delivery structure 39 may be spaced apart from the RF delivery structure 37 in a horizontal direction. The heater power delivery structure 39 may be provided to electrically connect the heater power supplying device HS to the heater 35. The heater power delivery structure 39 may apply a heating power to the heater 35. In other words, the heating power may be supplied to the heater 35 through the heating power delivery structure 39. In some embodiments, the heating power may be, for example, an AC power. Due to the heating power applied to the heater 35 through the heater power delivery structure 39, the heater 35 may exhaust heat to a neighboring space or neighboring elements. Thus, the heating plate 31 and/or the substrate on the heating plate 31 may be heated. In an embodiment, a plurality of heater power delivery structures 39 may be provided. For example, in the case where the heater 35 is provided in the form of two or more separated heating lines, the heater power delivery structures 39 may be connected to the heating lines, respectively. However, for convenience in description, the description that follow will refer to an example, in which one heater power delivery structure 39 is provided. The heater power delivery structure 39 will be described in more detail below.

The protection shaft 38 may be provided to enclose at least a portion of the RF delivery structure 37 and/or at least a portion of the heater power delivery structure 39. In other words, at least a portion of the RF delivery structure 37 and/or at least a portion of the heater power delivery structure 39 may be placed in the protection shaft 38. The protection shaft 38 may be formed of or include at least one of ceramic materials, but the embodiments are not limited to this example.

The shower head 5 may be spaced apart from the substrate supporting apparatus 3 in an upward direction. More specifically, the shower head 5 may be spaced apart from the heating plate 31 in an upward direction by a specific distance. The shower head 5 may be provided to have a plurality of ejection holes (not referenced). The ejection holes may be spaced apart from each other in a horizontal direction. A process gas, which is supplied from the gas supplying device GS, may be uniformly supplied into the process space 1h through the ejection holes of the shower head 5.

The gas supplying device GS may be connected to the chamber 1. The gas supplying device GS may be configured to supply the process gas into the process space 1h. For this, the gas supplying device GS may include a gas tank, a compressor, and/or at least one valve.

The RF power supplying device RS may be connected to the RF delivery structure 37. For example, the RF power supplying device RS may be connected electrically to the RF delivery structure 37. The RF power supplying device RS may be configured to supply the RF power to the RF electrode 33 through the RF delivery structure 37.

The heater power supplying device HS may be connected to the heater power delivery structure 39. For example, the heater power supplying device HS may be connected electrically to the heater power delivery structure 39. The heater power supplying device HS may be configured to apply the heating power to the heater 35 through the heater power delivery structure 39.

The pump VP may be connected to the exhaust port EP. In an embodiment, the pump VP may include a vacuum pump. The pump VP may be used to exhaust a fluidic material in the process space 1h to the outside.

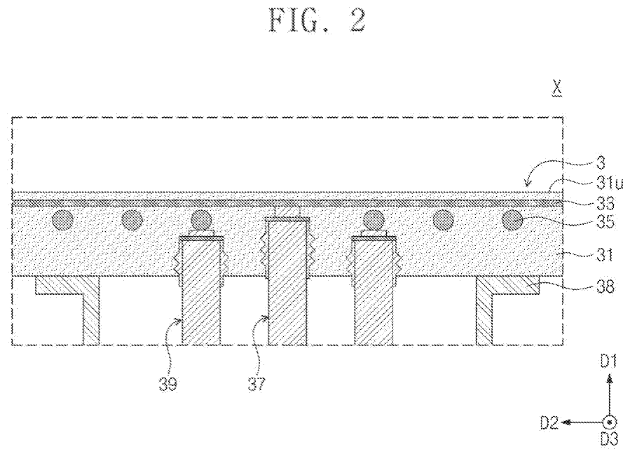

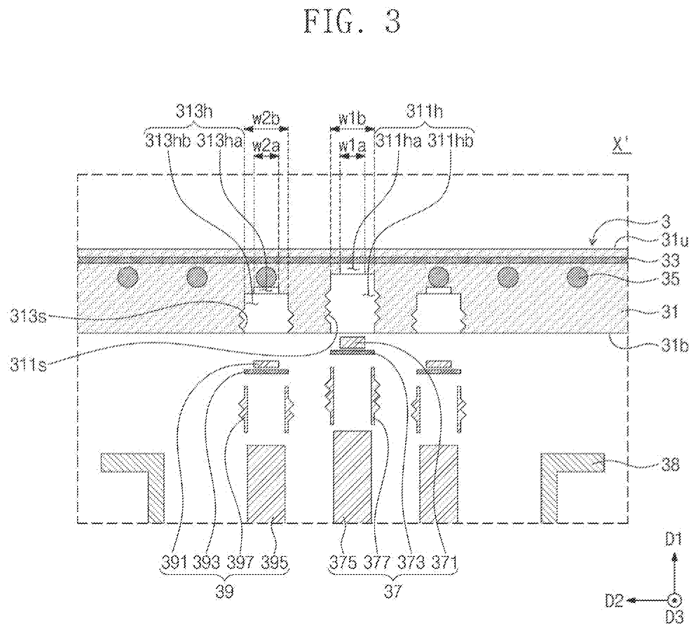

FIG. 2 is an enlarged sectional view illustrating a portion ‘X’ of FIG. 1, and FIG. 3 is an exploded sectional view of FIG. 2, according to some embodiments.

Referring to FIGS. 2 and 3, the heating plate 31 may be provided to include a first insertion hole 311h and a second insertion hole 313h.

The first insertion hole 311h may be a hole, which is recessed into the heating plate 31 from a bottom surface 31b of the heating plate 31 in an upward direction. The first insertion hole 311h may be provided to expose a bottom surface of the RF electrode 33. A portion of the RF delivery structure 37 may be inserted in the first insertion hole 311h. The first insertion hole 311h may include a first upper insertion hole 311ha and a first lower insertion hole 311hb. The first upper insertion hole 311ha may be provided to expose the bottom surface of the RF electrode 33. The first lower insertion hole 311hb may be extended from the first upper insertion hole 311ha in a downward direction. The first lower insertion hole 311hb may be connected to the bottom surface 31b of the heating plate 31. The first lower insertion hole 311hb may be formed to have a female thread structure 311s. In other words, the female thread structure 311s may be provided on an inner side surface of the heating plate 31 defining the first lower insertion hole 311hb. A width w1b (i.e., a diameter) of the first lower insertion hole 311hb may be larger than a width w1a (i.e., a diameter) of the first upper insertion hole 311ha. However, the embodiments are not limited to this example.

The second insertion hole 313h may be a hole, which is recessed into the heating plate 31 from the bottom surface 31b of the heating plate 31 in an upward direction. The second insertion hole 313h may be spaced apart from the first insertion hole 311h in a horizontal direction. The second insertion hole 313h may be provided to expose the heater 35. A portion of the heater power delivery structure 39 may be inserted in the second insertion hole 313h. The second insertion hole 313h may include a second upper insertion hole 313ha and a second lower insertion hole 313hb. The second upper insertion hole 313ha may be provided to expose the heater 35. The second lower insertion hole 313hb may be extended from the second upper insertion hole 313ha in a downward direction. The second lower insertion hole 313hb may be connected to the bottom surface 31b of the heating plate 31. The second lower insertion hole 313hb may be provided to have a female thread structure 313s. In other words, the female thread structure 313s may be provided on an inner side surface of the heating plate 31 defining the second lower insertion hole 313hb. A width w2b (i.e., a diameter) of the second lower insertion hole 313hb may be larger than a width w2a (i.e., a diameter) of the second upper insertion hole 313ha. However, the embodiments are not limited to this example.

The RF delivery structure 37 may include a first coupling member 371, a first filler 373, an RF rod 375, and a first connecting member 377.

The first coupling member 371 may be inserted in the first upper insertion hole 311ha. The first coupling member 371 may be in contact with the bottom surface of the RF electrode 33. The first coupling member 371 may be formed of or include at least one of conductive materials. For example, the first coupling member 371 may be formed of or include molybdenum (Mo).

The first filler 373 may be in contact with a bottom surface of the first coupling member 371. The first filler 373 may be inserted in the first upper insertion hole 311ha. The first filler 373 may be formed of or include gold (Au), but the embodiments are not limited to this example.

The RF rod 375 may be extended from the first filler 373 in a downward direction. The RF rod 375 may have a shape of a vertically-extended rod. A portion of the RF rod 375 may be inserted in the first upper insertion hole 311ha. The RF rod 375 may be electrically connected to the RF power supplying device RS (e.g., see FIG. 1). The RF rod 375 may be formed of or include a first material. The first material may be chosen to have physical properties that are suitable for transmission of the RF power. For example, the first material may be chosen to have the following physical properties.

A relative permeability of the first material may be less than about 150. In some embodiments, the relative permeability of the first material may range from about 1 to about 100.

A volume resistivity of the first material may be smaller than about 90 nΩm. In some embodiments, the volume resistivity of the first material may range from about 1nΩm to about 70nΩm.

A melting point of the first material may be higher than about 1000° C. In some embodiments, the melting point of the first material may range from about 1400° C. to about 4000° C.

In an embodiment, the first material may include molybdenum (Mo) and/or rhodium (Rh), but the embodiments are not limited to this example. In the case where the first material is molybdenum (Mo), the RF rod 375 may include a material, which is substantially the same as or similar to the first coupling member 371.

The first connecting member 377 may be placed below the first coupling member 371. The first connecting member 377 may enclose the RF rod 375 in the first insertion hole 311h. For example, a portion of the RF rod 375 may be inserted in the first connecting member 377. A portion of the first connecting member 377 may protrude in a downward direction, relative to the bottom surface 31b of the heating plate 31, but the embodiments are not limited to this example. The first connecting member 377 may include a male thread structure. The first connecting member 377 may be in gear with the female thread structure 311s of the first lower insertion hole 311hb. In an embodiment, the first connecting member 377 may be formed of or include molybdenum (Mo), but the embodiments are not limited to this example.

The heater power delivery structure 39 may include a second coupling member 391, a second filler 393, a heater power rod 395, and a second connecting member 397.

The second coupling member 391 may be inserted in the second upper insertion hole 313ha. The second coupling member 391 may be in contact with the heater 35. The second coupling member 391 may be formed of or include at least one of conductive materials. For example, the second coupling member 391 may be formed of or include molybdenum (Mo).

The second filler 393 may be in contact with a bottom surface of the second coupling member 391. The second filler 393 may be inserted in the second lower insertion hole 313hb. The second filler 393 may be formed of or include gold (Au), but the embodiments are not limited to this example.

The heater power rod 395 may be extended from the second filler 393 in a downward direction. The heater power rod 395 may have a shape of a vertically-extended rod. A portion of the heater power rod 395 may be inserted in the second lower insertion hole 313hb. The heater power rod 395 may be electrically connected to the heater power supplying device HS (e.g., see FIG. 1). The heater power rod 395 may be formed of or include a material that is substantially the same as or similar to the RF rod 375. For example, the heater power rod 395 may be formed of or include the first material.

The second connecting member 397 may be placed below the second coupling member 391. The second connecting member 397 may enclose the heater power rod 395 in the second insertion hole 313h. In other words, a portion of the heater power rod 395 may be inserted in the second connecting member 397. A portion of the second connecting member 397 may protrude in a downward direction, relative to the bottom surface 31b of the heating plate 31, but the embodiments are not limited to this example. The second connecting member 397 may include a male thread structure. The second connecting member 397 may be in gear with the female thread structure 313s of the second lower insertion hole 313hb. In an embodiment, the second connecting member 397 may be formed of or include molybdenum (Mo), but the embodiments are not limited to this example.

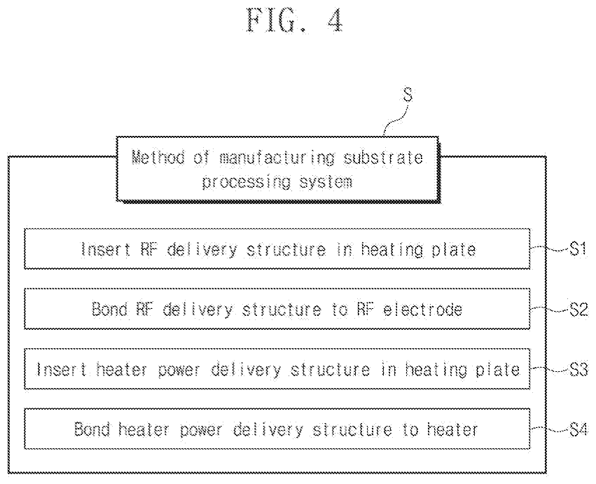

FIG. 4 is a flow chart illustrating a method of manufacturing a substrate processing system, according to some embodiments.

Referring to FIG. 4, a method of manufacturing a substrate processing system S may be provided. The manufacturing method S may be used to manufacture the substrate processing system A described with reference to FIGS. 1 to 3. The manufacturing method S may include inserting an RF delivery structure in a heating plate (in S1), bonding the RF delivery structure to an RF electrode (in S2), inserting a heater power delivery structure in a heating plate (in S3), and bonding the heater power delivery structure to a heater (in S4).

Hereinafter, the manufacturing method of FIG. 4 will be described in more detail with reference to FIGS. 5 to 8.

FIGS. 5 to 8 are sectional views sequentially illustrating a method of manufacturing a substrate processing system according to the flow chart of FIG. 4.

Referring to FIGS. 5 and 4, the inserting of the RF delivery structure in the heating plate (in S1) may include inserting the first coupling member 371 in the first upper insertion hole 311ha. The first coupling member 371, which is inserted in the first upper insertion hole 311ha, may be in contact with the bottom surface of the RF electrode 33.

The inserting of the heater power delivery structure in the heating plate (in S3) may include inserting the second coupling member 391 in the second upper insertion hole 313ha. The second coupling member 391, which is inserted in the second upper insertion hole 313ha, may be in contact with the heater 35.

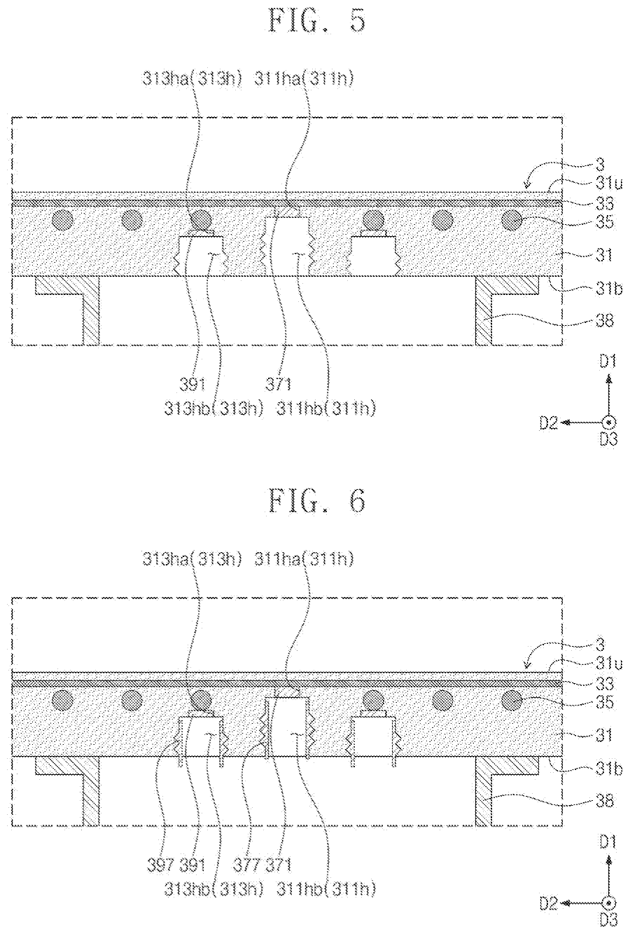

Referring to FIGS. 6 and 4, the inserting of the RF delivery structure in the heating plate (in S1) may further include inserting the first connecting member 377 in the first lower insertion hole 311hb. The first connecting member 377 may be rotated and inserted such that the male thread structure of the first connecting member 377 is in gear with the female thread structure of the first lower insertion hole 311hb.

The inserting of the heater power delivery structure in the heating plate (in S3) may further include inserting the second connecting member 397 in the second lower insertion hole 313hb. The second connecting member 397 may be rotated and inserted such that the male thread structure of the second connecting member 397 is in gear with the female thread structure of the second lower insertion hole 313hb.

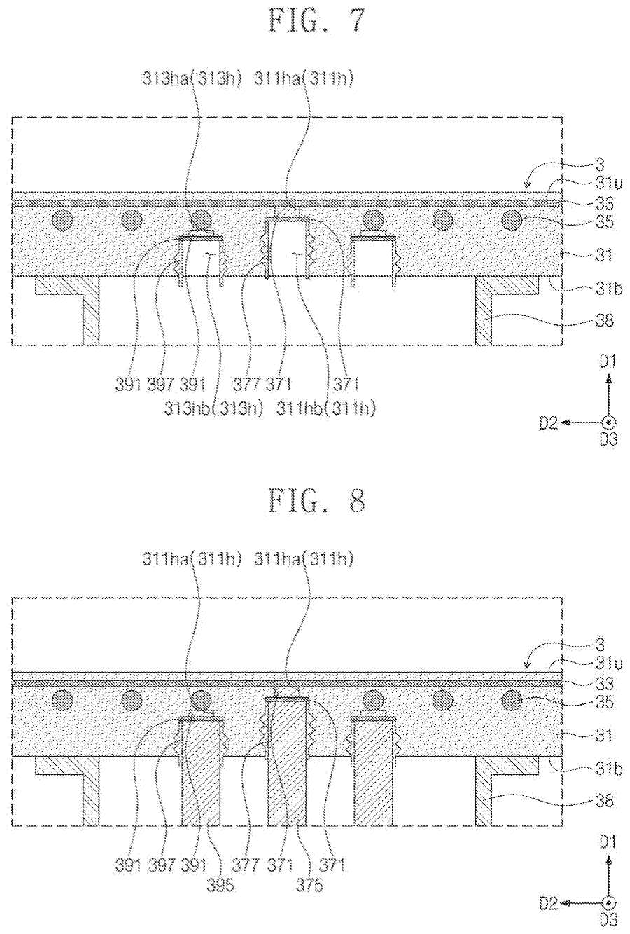

Referring to FIGS. 7 and 4, the inserting of the RF delivery structure in the heating plate (in S1) may further include inserting the first filler 373 in the first lower insertion hole 311hb. The first filler 373, which is inserted in the first lower insertion hole 311hb, may be in contact with the bottom surface of the first coupling member 371 and/or the first connecting member 377.

The inserting of the heater power delivery structure in the heating plate (in S3) may further include inserting the second filler 393 in the second lower insertion hole 313hb. The second filler 393, which is inserted in the second lower insertion hole 313hb, may be in contact with a bottom surface of the second coupling member 391 and/or the second connecting member 397.

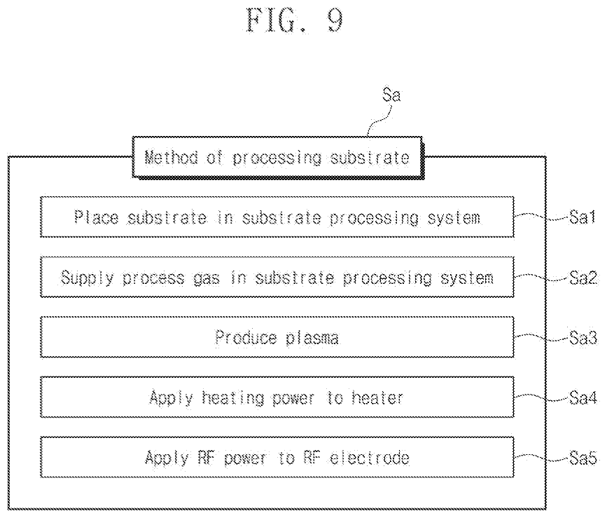

Referring to FIGS. 8 and 4, the inserting of the RF delivery structure in the heating plate (in S1) may further include inserting the RF rod 375 in the first lower insertion hole 311hb. The RF rod 375 may be inserted in the first connecting member 377. The RF rod 375 may be in contact with a bottom surface of the first filler 373.

The inserting of the heater power delivery structure in the heating plate (in S3) may further include inserting the heater power rod 395 in the second lower insertion hole 313hb. The heater power rod 395 may be inserted in the second connecting member 397. The heater power rod 395 may be in contact with a bottom surface of the second filler 393.

The bonding of the RF delivery structure to the RF electrode (in S2) may include heating the heating plate 31 when the RF rod 375 is in contact with the bottom surface of the first filler 373. The first filler 373 may be melted and solidified, and in this case, the RF rod 375 may be electrically connected to the first coupling member 371 through the first filler 373. In an embodiment, the first filler 373 may be melted and solidified to bond the RF rod 375 to the first connecting member 377.

The bonding of the heater power delivery structure to the heater (in S4) may include heating the heating plate 31, when the heater power rod 395 is in contact with the bottom surface of the second filler 393. The second filler 393 may be melted and solidified, and in this case, the heater power rod 395 may be electrically connected the second coupling member 391 through the second filler 393. In an embodiment, the second filler 393 may be melted and solidified to bond the heater power rod 395 to the second connecting member 397.

In a substrate supporting apparatus according to some embodiments, a substrate processing system including the same, and a method of manufacturing the same, the RF electrode, the first coupling member, and the RF rod may be formed of or include the same material. Thus, even when the RF electrode, the first coupling member, and the RF rod are heated, it may be possible to reduce a difference in thermal expansion among the RF electrode, the first coupling member, and the RF rod. Accordingly, the bonding structure between the RF electrode, the first coupling member, and the RF rod may be robustly maintained.

In a substrate supporting apparatus according to some embodiments, a substrate processing system including the same, and a method of manufacturing the same, the connecting member with the thread structure may be used to connect the rod to the heating plate. This configuration may make it possible to simplify the process of manufacturing the substrate supporting apparatus and to execute the process quickly.

FIG. 9 is a flow chart illustrating a substrate processing method according to some embodiments.

Referring to FIG. 9, a substrate processing method Sa may be provided. The substrate processing method Sa may be used to process a substrate using the substrate processing system A described with reference to FIGS. 1 to 3. The substrate processing method Sa may include placing a substrate in a substrate processing system (in Sa1), supplying a process gas in the substrate processing system (in Sa2), producing plasma (in Sa3), applying a heating power to a heater (in Sa4), and applying an RF power to an RF electrode (in Sa5).

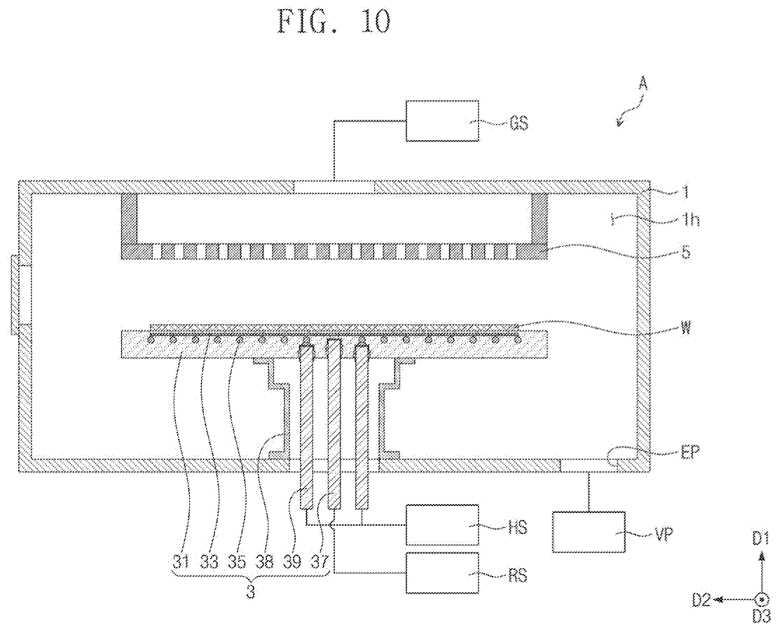

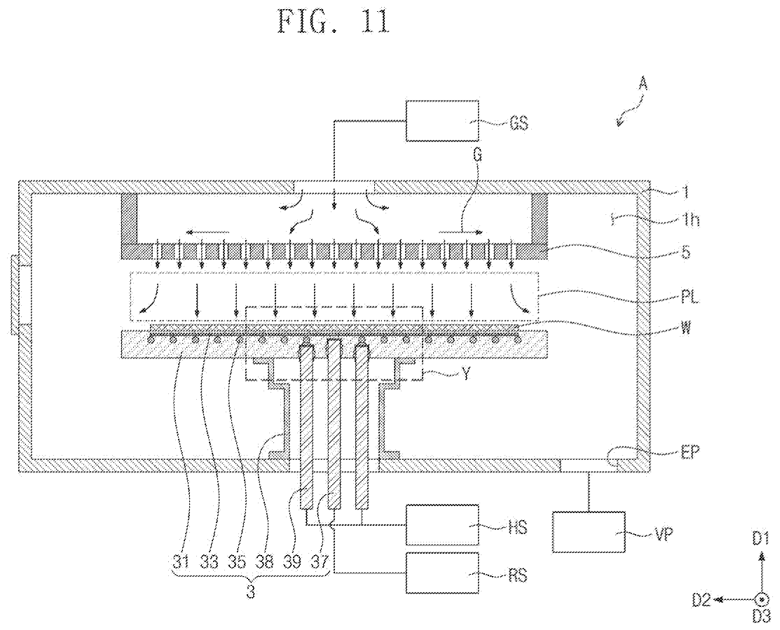

Hereinafter, the substrate processing method Sa of FIG. 9 will be described in more detail with reference to FIGS. 10 to 12.

FIGS. 10 to 12 are sectional views illustrating a substrate processing method according to the flow chart of FIG. 9, according to some embodiments.

Referring to FIGS. 10 and 9, the placing of the substrate in the substrate processing system (in Sa1) may include placing a substrate W on the substrate supporting apparatus 3. The substrate supporting apparatus 3 may be configured to fasten the substrate W to a specific position.

Referring to FIGS. 11 and 9, the supplying of the process gas in the substrate processing system (in Sa2) may include supplying a process gas G from the gas supplying device GS to the process space 1h. The process gas G may be uniformly supplied into the process space 1h by the shower head 5.

The producing of the plasma (in Sa3) may include producing plasma PL from a portion of the process gas G. For example, the portion of the process gas G may be changed to the plasma PL by a CCP method. The plasma PL may be used to treat the substrate W.

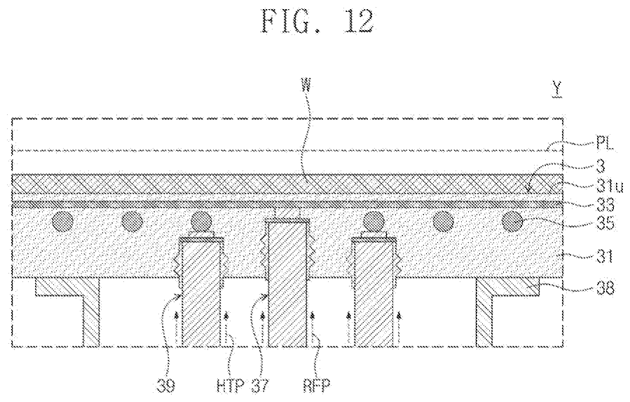

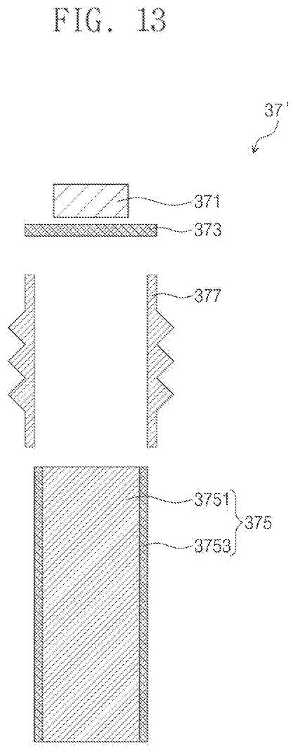

Referring to FIGS. 12 and 9, the applying of the heating power to the heater (in Sa4) may include applying a heating power HTP to the heater 35 through the heater power delivery structure 39. In an embodiment, the heating power HTP may be an AC power. The heater 35 may be configured to exhaust heat energy, which is generated from the heating power HTP, to a neighboring space or neighboring element.

The applying of the RF power to the RF electrode (in Sa5) may include applying an RF power RFP to the RF electrode 33 through the RF delivery structure 37. The RF power RFP may be used to fasten the RF electrode 33 to the substrate W or to control the plasma PL.

In a substrate supporting apparatus according to some embodiments, a substrate processing system including the same, and a method of manufacturing the same, the RF rod may be formed of or include molybdenum (Mo). Since the molybdenum (Mo) has a large skin depth, the use of the molybdenum (Mo) may make it possible to transmit the RF power through the rod at a low resistance. Accordingly, it may be possible to reduce loss of the power. In some embodiments, it may be possible to reduce an amount of heat generated from the RF rod. Thus, it may be possible to prevent the heating plate from being thermally damaged. For example, even when a strong RF power is applied, the RF rod may not be damaged.

In a substrate supporting apparatus according to some embodiments, a substrate processing system including the same, and a method of manufacturing the same, not only the RF rod but also the heater power rod may be formed of or include molybdenum (Mo). Thus, it may be possible to reduce an amount of heat from the heater power rod. Accordingly, it may be possible to prevent the heating plate from being thermally damaged.

FIG. 13 is an exploded sectional view illustrating an RF delivery structure according to some embodiments.

In the following description, an element previously described with reference to FIGS. 1 to 12 may be identified by the same reference number without repeating an overlapping description thereof, for concise description.

Referring to FIG. 13, an RF delivery structure 37′ may include the first coupling member 371, the first filler 373, the RF rod 375, and the first connecting member 377. Here, the RF rod 375 may be provided to include an RF rod body 3751 and a RF rod coating layer 3753, unlike the embodiment of FIG. 3.

The RF rod body 3751 may have a shape of a vertically-extended rod. The RF rod body 3751 may be formed of or include the first material. For example, the RF rod body 3751 may be formed of or include molybdenum (Mo).

The RF rod coating layer 3753 may be provided on an outer surface of the RF rod body 3751. In an embodiment, the RF rod coating layer 3753 may be provided to enclose the RF rod body 3751. The RF rod coating layer 3753 may be formed of or include a material different form the RF rod body 3751. For example, the RF rod coating layer 3753 may be formed of or include a second material. The second material may be different from the first material. For example, in some embodiments, the second material may include a ceramic material.

In a substrate supporting apparatus according to some embodiments, a substrate processing system including the same, and a method of manufacturing the same, a coating layer may be provided to cover the RF rod. In this case, it may be possible to prevent the RF rod body, which contains the molybdenum, from being oxidized. Furthermore, in the case where the coating layer on the RF rod contains a ceramic material, the coating layer may not be melted even when the RF rod is heated to a very high temperature. Thus, the apparatus may have an increased lifetime.

In a substrate supporting apparatus according to some embodiments, a substrate processing system including the same, and a method of manufacturing the same, it may be possible to economize on electric power.

In a substrate supporting apparatus according to some embodiments, a substrate processing system including the same, and a method of manufacturing the same, it may be possible to reduce heat generated therein.

In a substrate supporting apparatus according to some embodiments, a substrate processing system including the same, and a method of manufacturing the same, it may be possible to increase a lifetime of the substrate supporting apparatus.

In a substrate supporting apparatus according to some embodiments, a substrate processing system including the same, and a method of manufacturing the same, it may be possible to simplify a process of assembling the substrate supporting apparatus.

While various example embodiments have been particularly shown and described, it will be understood by one of ordinary skill in the art that variations in form and detail may be made therein without departing from the spirit and scope of the attached claims.

1. A substrate supporting apparatus comprising:
a heating plate;
a radio frequency (RF) electrode in the heating plate; and
an RF delivery structure in contact with a bottom surface of the RF electrode,
wherein the heating plate includes a first insertion hole, which is recessed into the heating plate from a bottom surface of the heating plate to expose the bottom surface of the RF electrode,
the RF delivery structure includes an RF rod, a portion of which is inserted in the first insertion hole, and through which an RF power is supplied to the RF electrode,
the RF rod comprises a first material,
a relative permeability of the first material is less than 100,
a volume resistivity of the first material is smaller than 70 nΩm, and
a melting point of the first material is higher than 1400° C.

2. The substrate supporting apparatus of claim 1, wherein the first material comprises molybdenum.

3. The substrate supporting apparatus of claim 1, wherein the RF rod comprises:
an RF rod body; and
an RF rod coating layer on an outer surface of the RF rod body,
wherein the RF rod body comprises the first material, and
the RF rod coating layer comprises a second material different from the first material.

4. The substrate supporting apparatus of claim 3, wherein the second material comprises a ceramic material.

5. The substrate supporting apparatus of claim 1, wherein the RF delivery structure further comprises:
a first coupling member, which is inserted in the first insertion hole and is in contact with the bottom surface of the RF electrode; and
a first filler, which is in contact with a bottom surface of the first coupling member,
wherein the RF rod is extended vertically from the first filler.

6. The substrate supporting apparatus of claim 5, wherein the first insertion hole comprises:
a first upper insertion hole, in which the first coupling member is inserted; and
a first lower insertion hole, which is extended vertically from the first upper insertion hole,
wherein a diameter of the first lower insertion hole is larger than a diameter of the first upper insertion hole.

7. The substrate supporting apparatus of claim 1, further comprising:
a heater in the heating plate; and
a heater power delivery structure, which is in contact with the heater and is spaced apart from the RF delivery structure in a horizontal direction,
wherein the heating plate includes a second insertion hole, which is recessed into the heating plate from the bottom surface of the heating plate to expose the heater and is spaced apart from the first insertion hole in the horizontal direction,
the heater power delivery structure comprises a heater power rod, which is vertically extended and includes a portion that is inserted in the second insertion hole, and
the heater power rod comprises molybdenum.

8. A substrate processing system comprising:
a chamber providing a process space; and
a substrate supporting apparatus placed in the chamber to support a substrate,
wherein the substrate supporting apparatus comprises:
a heating plate;
a radio frequency (RF) electrode in the heating plate;
a heater in the heating plate;
an RF delivery structure in contact with a bottom surface of the RF electrode; and
a heater power delivery structure, which is in contact with the heater and is spaced apart from the RF delivery structure in a horizontal direction,
the heating plate comprises:
a first insertion hole, which is recessed into the heating plate from a bottom surface of the heating plate to expose the bottom surface of the RF electrode; and
a second insertion hole, which is recessed into the heating plate from the bottom surface of the heating plate to expose the heater and is spaced apart from the first insertion hole in the horizontal direction,
the RF delivery structure comprises an RF rod, which is vertically extended and includes a portion that is inserted in the first insertion hole,
the heater power delivery structure comprises a heater power rod, which is vertically extended and includes a portion that is inserted in the second insertion hole, and
each of the RF rod and the heater power rod comprises molybdenum.

9. The substrate processing system of claim 8, wherein the heater is placed vertically below the RF electrode, and
the heater includes two or more heating lines, which are provided to enclose a portion of the RF delivery structure when viewed in a plan view.

10. The substrate processing system of claim 8, wherein a length of the RF rod is longer than a length of the heater power rod.

11. The substrate processing system of claim 8, wherein a diameter of the second insertion hole is larger than a diameter of the first insertion hole.

12. The substrate processing system of claim 8, wherein the RF delivery structure comprises:
a first coupling member, which is inserted in the first insertion hole and is in contact with the bottom surface of the RF electrode; and
a first filler in contact with a bottom surface of the first coupling member, the heater power delivery structure further comprises:
a second coupling member, which is inserted in the second insertion hole and is in contact with the heater; and
a second filler, which is in contact with a bottom surface of the second coupling member,
the RF rod is extended vertically from the first filler,
the heater power rod is extended vertically from the second filler, and
each of the first coupling member and the second coupling member comprises molybdenum.

13. The substrate processing system of claim 12, wherein the RF delivery structure further comprises a first connecting member, which is placed vertically below the first coupling member and encloses the RF rod in the first insertion hole,
the heater power delivery structure further comprises a second connecting member, which is placed vertically below the second coupling member and encloses the heater power rod in the second insertion hole, and
each of the first connecting member and the second connecting member comprises a male thread structure.

14. The substrate processing system of claim 13, wherein the first insertion hole comprises:
a first upper insertion hole, in which the first coupling member is inserted; and
a first lower insertion hole, which is extended vertically from the first upper insertion hole,
the second insertion hole comprises:
a second upper insertion hole, in which the second coupling member is inserted; and
a second lower insertion hole, which is extended vertically from the second upper insertion hole,
a diameter of the first lower insertion hole is larger than a diameter of the first upper insertion hole, and
a diameter of the second lower insertion hole is larger than a diameter of the second upper insertion hole.

15. The substrate processing system of claim 14, wherein each of the first lower insertion hole and the second lower insertion hole comprises a female thread structure,
the male thread structure of the first connecting member is in gear with the female thread structure of the first lower insertion hole, and
the male thread structure of the second connecting member is in gear with the female thread structure of the second lower insertion hole.

16. The substrate processing system of claim 12, wherein each of the first filler and the second filler comprises gold.

17. The substrate processing system of claim 8, wherein the heater power delivery structure is provided in plural, and
the plurality of heater power delivery structures are spaced apart from each other in the horizontal direction.

18. The substrate processing system of claim 8, wherein the RF electrode comprises molybdenum.

19. The substrate processing system of claim 8, further comprising:
an RF power supplying device configured to supply an RF power to the RF delivery structure; and
a heater power supplying device configured to supply a heating power to the heater power delivery structure.

20. The substrate processing system of claim 8, wherein the substrate supporting apparatus further comprises a protection shaft, which encloses the RF rod and the heater power rod.

21.-25. (canceled)
